(19) United States
(12) Patent Application Publication
(10) Pub. No.: US 2026/0293691 A1
(43) Pub. Date: Sep. 24, 2026

(54) ADAPTIVE DESATURATION DETECTION METHOD FOR OVERCURRENT PROTECTION OF POWER SEMICONDUCTOR DEVICE, AND GATE DRIVER

(71) Applicant: Beijing National New Energy Vehicle Technology Innovation Center Co., Ltd., Beijing (CN)

(72) Inventors: Chaohui Liu, Beijing (CN); Zhaohe Meng, Beijing (CN); Enrico Vico, Beijing (CN); Fausto Stella, Beijing (CN); Davide Cittanti, Beijing (CN); Radu Bojoi, Beijing (CN); Guangcai Zou, Beijing (CN); Chengyin Yuan, Beijing (CN)

(73) Assignee: Beijing National New Energy Vehicle Technology Innovation Center Co., Ltd., Beijing (CN)

(21) Appl. No.: 19/475,483

(22) PCT Filed: Oct. 27, 2023
(86) PCT No.: PCT/CN2023/127311

§ 371 Date: Oct. 15, 2025

(30) Foreign Application Priority Data
Apr. 18, 2023 (CN) 202310415143.8

(51) Int. Cl. H10W 42/80; G01K 7/22; G01R 19/165

(52) U.S. Cl. CPC H10W 42/80; G01K 7/22; G01R 19/16576

(57) ABSTRACT

The present disclosure discloses an adaptive desaturation detection method for overcurrent protection of power semiconductor device and a gate driver, the desaturation detection method comprising: obtaining corresponding relationship between junction temperature and desaturation voltage threshold of the power semiconductor device; obtaining turn-on voltage and junction temperature of the power semiconductor device in real time; determining the voltage threshold corresponding to current junction temperature according to the corresponding relationship; judging whether the current turn-on voltage is greater than the voltage threshold corresponding to the current junction temperature, and if so, enabling the function of overcurrent protection. The present disclosure can adjust the level for triggering protection function according to the specific junction temperature of the power semiconductor device, so as to provide fast and accurate overcurrent protection function under all operating conditions.

### FIELD OF TECHNOLOGY

The present disclosure relates to the field of circuit technology, and more specifically, to an adaptive desaturation detection method for overcurrent protection of power semiconductor device and a gate driver.

### BACKGROUND

Desaturation protection function can provide protection for the power semiconductor device when the power semiconductor device has overcurrent or abnormal driving conditions (for example, when the device is turned on, the VGS voltage is insufficient), and play an important role in ensuring safe operation of power converters. This protection function can perform intervention very quickly (about 1-2 μs); as a comparison, the current sensor-based protection function requires response time of 10 to 100 μs. Power semiconductor devices can withstand short-circuit current (such as inverter phase-to-phase short-circuit current) for only a few microseconds, so in most cases, the desaturation protection function is the only effective way to avoid catastrophic failure of the device. From the point of view of traditional desaturation protection function, the turn-on voltage of the power device is used to indirectly detect the turn-on current of the device. In many gate drivers today, the desaturation detection function and related fault reporting function have been integrated into the low-voltage side digital signal processor/microcontroller.

The desaturation protection function indirectly detects the turn-on current in the device by utilizing the voltage drop during the device connection period. A schematic diagram of this aspect is shown in FIG. 1. If the voltage at two ends of the power device exceeds a specific voltage threshold V_{DESAT} (i.e. overcurrent is detected), a fault phenomenon will occur. The desaturation protection function usually utilizes the correlation between the turn-on voltage and conduction current of the semiconductor device. However, the junction temperature of the semiconductor device can greatly affect the turn-on voltage (for a power field-effect transistor, it is suitable for R_{DS}I_{DS}, while for an insulated gate bipolar transistor, it is suitable for V_{TH}+R_{CE}I_{CE}). Therefore, if the turn-on voltage remains constant, it may trigger the desaturation protection function at different current levels.

To solve this problem, which is to avoid accidentally triggering the desaturation protection function, the desaturation voltage threshold is usually set at a sufficiently high level. However, it is also possible to trigger the protection function in a larger current range, which depends on the junction temperature of the device.

In most commercial gate drivers, a desaturation protection function based on measurement of the turn-on voltage of the driven device has been integrated. Once the desaturation condition is detected, it indicates that the power semiconductor device has malfunctioned. In addition, besides the desaturation protection function, a soft disconnect function is provided for many commercial gate drivers (i.e., to disconnect the device at di/dt ratio lower than normal operating condition), thereby reducing the overvoltage applied to the driven semiconductor device at higher di/dt ratio during commutation to the greatest extent.

Usually, external circuit diagrams are used to set the triggering level for response delay and the desaturation protection function. Since the triggering level is fixed and cannot be adjusted during the operation of the converter, the designer has to set the triggering level high enough to avoid false triggering. When this level is set, it is usually considered to be the highest turn-on level the device can reach within the range of the operating junction temperature of the semiconductor device. The higher the triggering level, the easier it is to generate overcurrent, which may shorten the service life of the power device and even immediately cause device failure.

In addition, a “current mirror” can be used to achieve overcurrent protection function with fast response and higher accuracy. According to this solution, some device current is introduced into dedicated pins which can be connected to the splitter. A gate driver can be used to measure the voltage at two ends of the splitter, and fast overcurrent protection can be achieved based on the measured voltage. The FF400R07A01E3 manufactured by Infineon is a commercial device that adopts this solution. By adopting this solution, precise overcurrent protection function can be achieved. However, this solution is only applicable to limited power devices with integrated current mirror function.

There is an alternative solution in two-level voltage source inverters, which is to equip the main current sensor with a phase current sensor with lower accuracy but higher bandwidth. However, this solution is costly and cannot provide protection for the inverter when a short circuit occurs in the inverter bridge arm (in which case the short-circuit current flows directly through the two bridge arm switches and is independent of the phase output).

The current technology based on desaturation protection function has the following drawbacks:
The existing desaturation protection function utilizes a fixed voltage threshold, and once the junction temperature of the protected power device changes, it will trigger the protection function at different current levels.
For devices that have not yet clearly determined the desaturation range (such as SiC power field-effect transistors), even the most advanced desaturation protection function cannot play a significant role.
To prevent false triggering, setting the voltage threshold for triggering the desaturation protection function at a sufficiently high level can usually avoid immediate failure of the power device. However, if overcurrent continues to occur, it may shorten the service life of the power device.
Alternative solutions such as “current mirrors” are only applicable to devices that already have this function integrated.
Alternative solutions such as “fast phase current sensors” bring relatively high additional cost and cannot provide protection for the semiconductor device of the converter in certain fault states (such as bridge arm short circuit faults in two-level voltage source inverters).

Therefore, how to adjust the triggering level of the protection function according to the specific junction temperature of the protected device is currently an urgent problem to be solved.

### SUMMARY

The purpose of the present disclosure is to propose an adaptive desaturation detection method for overcurrent protection of power semiconductor device and a gate driver, which can adjust the level for triggering protection function according to the specific junction temperature of the power semiconductor device, so as to provide fast and accurate overcurrent protection function under all operating conditions.

Based on the above purpose, the present disclosure provides an adaptive desaturation detection method for overcurrent protection of power semiconductor device, comprising:
obtaining corresponding relationship between junction temperature and desaturation voltage threshold of the power semiconductor device;
obtaining turn-on voltage and junction temperature of the power semiconductor device in real time;
determining the voltage threshold corresponding to current junction temperature according to the corresponding relationship;
judging whether the current turn-on voltage is greater than the voltage threshold corresponding to the current junction temperature, and if so, enabling a function of overcurrent protection.

In an optional solution, the corresponding relationship between junction temperature and desaturation voltage threshold of the power semiconductor device is obtained according to a lookup table stored in a gate driver, and the gate driver is configured to drive the power semiconductor device.

In an optional solution, the lookup table is transmitted to the gate driver through a microcontroller.

In an optional solution, the lookup table is obtained by experimental characterization of the power semiconductor device or information provided in a handbook from a manufacturer of the power semiconductor device.

In an optional solution, the junction temperature is obtained by a thermistor or a thermal diode connected between a T.MEAS pin and a COM pin of the gate driver.

The present disclosure also provides a gate driver for driving a power semiconductor device, the gate driver comprising:
a storage unit, the storage unit stores corresponding relationship between junction temperature and desaturation voltage threshold of the power semiconductor device;
a detection unit, configured to obtain turn-on voltage and junction temperature of the power semiconductor device in real time;
a comparison unit, configured to determine whether the current turn-on voltage is greater than the voltage threshold corresponding to the current junction temperature;
a protection unit, configured to enable a function of overcurrent protection in response to a result that the current turn-on voltage is greater than the voltage threshold corresponding to the current junction temperature.

In an optional solution, the comparison unit is a comparator, one input terminal of the comparator is configured to input the current turn-on voltage, and the other input terminal is connected to an output terminal of the storage unit.

In an optional solution, a lookup table is stored in the storage unit, and the lookup table records the corresponding relationship, input of the storage unit is the junction temperature, and output is the desaturation voltage threshold corresponding to the junction temperature.

In an optional solution, the detection unit comprises a thermistor or a thermal diode connected between a T.MEAS pin and a COM pin of the gate driver, and is configured to output the detected junction temperature to the storage unit.

In an optional solution, the storage unit has a serial interface for receiving the lookup table through a microcontroller.

The beneficial effects of the present disclosure include:

The disclosure can adjust the level for triggering protection function according to the specific junction temperature of the power semiconductor device, so as to provide fast and accurate overcurrent protection function under all operating conditions.

The lookup table is programmed only once and an external controller (main microcontroller) is not required. This avoids unnecessary delay and at the same time improves the overall reliability of the system (for example, preventing possible communication failure between the driver and the microcontroller).

Since the designer no longer needs to reduce the high risk of false triggering of protection function (if the triggering level of the protection function is set to a lower level, there may be this risk) at the cost of shortening the service life of the device (setting the triggering level of the protection function to a higher level will generate more overcurrent, thereby shortening the service life), the design difficulty of the desaturation protection function is reduced.

The present disclosure has other features and advantages which will be apparent from or will be apparent from the drawings and detailed description that follow, incorporated herein. The drawings and detailed description serve together to explain certain principles of the disclosure, being set forth in detail.

### BRIEF DESCRIPTION OF THE DRAWINGS

The above and other objects, features and advantages of the present disclosure will become more apparent by describing the exemplary embodiments of the present disclosure in more detail with reference to the accompanying drawings.

FIG. 1 shows working schematic diagram of desaturation protection function of the gate driver.

FIG. 2 shows schematic structural diagram of a gate driver according to an embodiment of the present disclosure.

FIG. 3 shows an example of lookup table for the ROHM BSM180D12P3C007 SiC power field effect transistor.

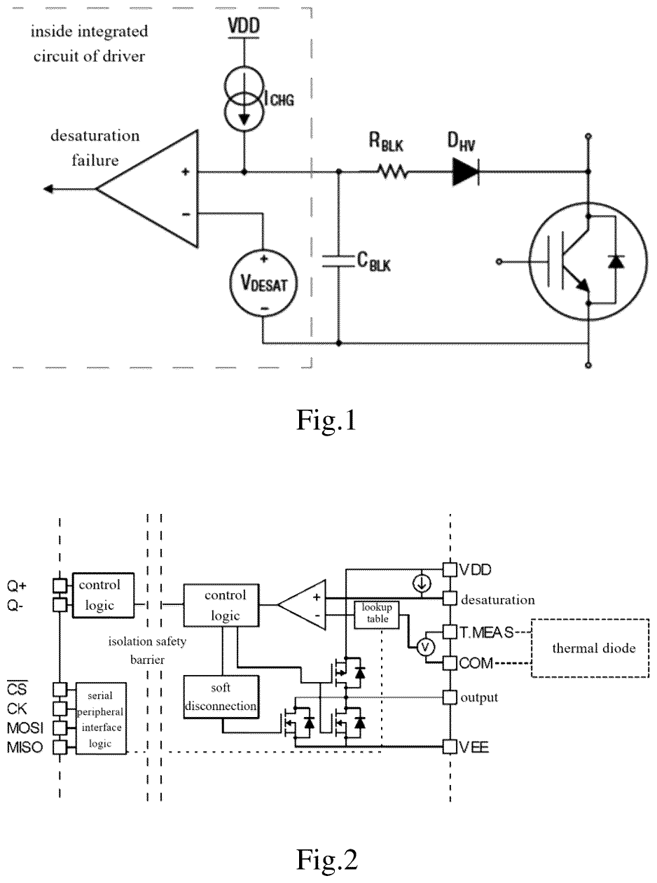

### DESCRIPTION OF THE EMBODIMENTS

The present disclosure will be described in more detail below. While the present disclosure has provided preferred embodiments, it should be understood that the disclosure can be embodied in various forms and should not be limited by the embodiments set forth herein. Rather, these embodiments are provided so that this disclosure will be thorough and complete, and will fully convey the scope of the disclosure to those skilled in the art.

### Embodiment 1

The present embodiment provides an adaptive desaturation detection method for overcurrent protection of power semiconductor device, comprising:
obtaining corresponding relationship between junction temperature and desaturation voltage threshold of the power semiconductor device;
obtaining turn-on voltage and junction temperature of the power semiconductor device in real time;
determining the voltage threshold corresponding to current junction temperature according to the corresponding relationship;
judging whether the current turn-on voltage is greater than the voltage threshold corresponding to the current junction temperature, and if so, enabling function of overcurrent protection.

In this embodiment, the corresponding relationship between junction temperature and desaturation voltage threshold of the power semiconductor device is obtained according to a lookup table stored in a gate driver, and the gate driver is configured to drive the power semiconductor device. The lookup table is transmitted to the gate driver through a microcontroller.

In this embodiment, the lookup table is obtained by experimental characterization of the power semiconductor device or information provided in a handbook from a manufacturer of the power semiconductor device.

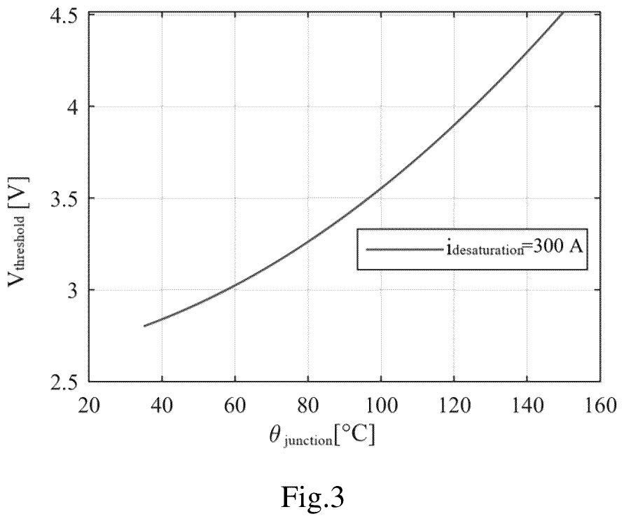

Specifically, in a specific example, the junction temperature of the power device is measured by a thermistor or a thermal diode connected between a T.MEAS pin and a COM pin of an integrated circuit driver. The measured temperature value is then input into a lookup table (LUT) to output a level suitable for triggering the desaturation protection function. The lookup table includes the turn-on voltage of the driven semiconductor device under the considered gate driving voltage and the target desaturation current value related to the junction temperature (that is a one-dimensional lookup table). In FIG. 3, an example of a ROHM BSM180D12P3C007 SiC power field effect transistor is shown, wherein the calculated Vgs=18V, and the target desaturation current is 300 A.

The lookup table can be obtained by experimental characterization (for example, using a curve plotter) of the power semiconductor device or information provided in a handbook (for example, typically listing the device's conduction characteristics in terms of gate-source driving voltage and junction temperature) from the manufacturer of the power semiconductor device. The information in the lookup table can be transmitted from the microcontroller to the driver through a serial peripheral interface (as shown in FIG. 2) or similar communication interface, and stored in the driver. After completing the programming of the lookup table and temperature measurement of the semiconductor device, linear interpolation algorithm is used to return the voltage threshold which is compared with the result of the desaturation voltage measurement. In this way, the overcurrent protection function can be quickly and accurately implemented without being affected by the device junction temperature.

The desaturation protection function of this embodiment can determine the current level that triggers the protection function without being affected by temperature, so as to realize a fast, accurate and unified over-current protection function.

The lookup table is programmed only once and an external controller (main microcontroller) is not required, which avoids unnecessary delay and at the same time improves the overall reliability of the system (for example, preventing possible communication failure between the driver and the microcontroller).

Since the designer no longer needs to reduce the high risk of accidental triggering of the protection function (if the triggering level of the protection function is set to a lower level, there may be this risk) at the cost of shortening device service life (setting the triggering level of the protection function to a higher level will generate more overcurrent, thereby shortening device service life), the design difficulty of the desaturation protection function is reduced.

### Embodiment 2

Referring to FIG. 2, the embodiment provides a gate driver for driving a power semiconductor device, the gate driver comprising:
a storage unit, the storage unit stores corresponding relationship between junction temperature and desaturation voltage threshold of the power semiconductor device;
a detection unit, configured to obtain turn-on voltage and junction temperature of the power semiconductor device in real time;
a comparison unit, configured to determine whether the current turn-on voltage is greater than the voltage threshold corresponding to the current junction temperature;
a protection unit, configured to enable function of overcurrent protection in response to a result that the current turn-on voltage is greater than the voltage threshold corresponding to the current junction temperature.

In the present embodiment, the comparison unit is a comparator, one input terminal of the comparator is configured to input the current turn-on voltage, and the other input terminal is connected to an output terminal of the storage unit.

In the present embodiment, a lookup table is stored in the storage unit, and the lookup table records the corresponding relationship, input of the storage unit is the junction temperature, and output is the desaturation voltage threshold corresponding to the junction temperature. The detection unit comprises a thermistor or a thermal diode connected between a T.MEAS pin and a COM pin of the gate driver, and is configured to output the detected junction temperature to the storage unit. The storage unit has a serial interface for receiving the lookup table through a microcontroller.

The gate driver structure of this embodiment includes an internal lookup table, wherein the lookup table takes the junction temperature of the power device as input, and outputs a voltage threshold suitable for triggering the desaturation protection function. The triggering level of the desaturation protection function depends on the junction temperature of the power semiconductor device, and the overcurrent protection function can be realized without being affected by temperature. This lookup table can be programmed externally through a digital interface.

The disclosure can adjust the level that triggers the protection function according to the specific junction temperature of the power semiconductor device, so as to provide fast and accurate overcurrent protection function under all operating conditions.

Various embodiments of the present disclosure have been described above, the foregoing description is exemplary, not exhaustive, and is not limited to the disclosed embodiments. Many modifications and alterations will be apparent to those of ordinary skill in the art without departing from the scope and spirit of the described embodiments.

What is claimed is:

1. An adaptive desaturation detection method for overcurrent protection of power semiconductor device, comprising:
obtaining corresponding relationship between junction temperature and desaturation voltage threshold of the power semiconductor device;
obtaining turn-on voltage and junction temperature of the power semiconductor device in real time;
determining the voltage threshold corresponding to current junction temperature according to the corresponding relationship;
judging whether current turn-on voltage is greater than the voltage threshold corresponding to current junction temperature, and if so, enabling a function of overcurrent protection.

2. The adaptive desaturation detection method for overcurrent protection of power semiconductor device according to claim 1, wherein, the corresponding relationship between junction temperature and desaturation voltage threshold of the power semiconductor device is obtained according to a lookup table stored in a gate driver, and the gate driver is configured to drive the power semiconductor device.

3. The adaptive desaturation detection method for overcurrent protection of power semiconductor device according to claim 2, wherein, the lookup table is transmitted to the gate driver through a microcontroller.

4. The adaptive desaturation detection method for overcurrent protection of power semiconductor device according to claim 2, wherein, the lookup table is obtained by experimental characterization of the power semiconductor device or information provided in a handbook from a manufacturer of the power semiconductor device.

5. The adaptive desaturation detection method for overcurrent protection of power semiconductor device according to claim 2, wherein, the junction temperature is obtained by a thermistor or a thermal diode connected between a T.MEAS pin and a COM pin of the gate driver.

6. A gate driver for driving a power semiconductor device, the gate driver comprising:
a storage unit, the storage unit stores corresponding relationship between junction temperature and desaturation voltage threshold of the power semiconductor device;
a detection unit, configured to obtain turn-on voltage and junction temperature of the power semiconductor device in real time;
a comparison unit, configured to determine whether current turn-on voltage is greater than the voltage threshold corresponding to current junction temperature;
a protection unit, configured to enable a function of overcurrent protection in response to a result that the current turn-on voltage is greater than the voltage threshold corresponding to the current junction temperature.

7. The gate driver of claim 6, wherein, the comparison unit is a comparator, one input terminal of the comparator is configured to input the current turn-on voltage, and the other input terminal is connected to an output terminal of the storage unit.

8. The gate driver according to claim 7, wherein, a lookup table is stored in the storage unit, and the lookup table records the corresponding relationship, input of the storage unit is the junction temperature, and output of the storage unit is the desaturation voltage threshold corresponding to the junction temperature.

9. The gate driver according to claim 8, wherein, the detection unit comprises a thermistor or a thermal diode connected between a T.MEAS pin and a COM pin of the gate driver, and is configured to output the detected junction temperature to the storage unit.

10. The gate driver according to claim 8, wherein, the storage unit has a serial interface for receiving the lookup table through a microcontroller.
